(19) United States
(12) Patent Application Publication
(10) Pub. No.: US 2026/0302723 A1
(43) Pub. Date: Oct. 1, 2026

(54) THERMAL ISOLATION OF LASER ENGINES IN HIGH DENSITY OPTO-ELECTRONIC INTERCONNECTION ASSEMBLIES

(71) Applicant: AAYUNA INC., Allentown, PA (US)

(72) Inventors: Kalpendu SHASTRI, Orefield, PA (US); Soham PATHAK, Allentown, PA (US); Sriram TYAGARAJAN, Macungie, PA (US); Alan LEONHARTSBERGER, Kempton, PA (US); Rutvij DAVE, Allentown, PA (US); Andrew RASELEY, Nazareth, PA (US); Steven E. STRAUSS, Orefield, PA (US); Ravinder KACHRU, San Jose, CA (US); Anujit SHASTRI, Saratoga, CA (US); David SNYDER, Coopersburg, PA (US); Rao YELAMARTY, Allentown, PA (US)

(73) Assignee: AAYUNA INC., Allentown, PA (US)

(21) Appl. No.: 19/477,379

(22) PCT Filed: Apr. 10, 2024
(86) PCT No.: PCT/US2024/023772

§ 371 Date: Oct. 21, 2025

Related U.S. Application Data
(60) Provisional application No. 63/460,983, filed on Apr. 21, 2023.

(51) Int. Cl. H01S 5/024; G02B 6/42

(52) U.S. Cl. CPC H01S 5/02469; G02B 6/4206; G02B 6/4269; G02B 6/4271; H01S 5/02415

(57) ABSTRACT

A high density opto-electronic interconnection assembly is proposed that eliminates the need for a relatively large physical separation between the laser source and associated opto-electronic circuitry and, as a result, eliminates the need to utilize optical fibers to provide coupling between the laser source and a photonic integrated circuit including optical waveguides. The laser source and the PIC are disposed on an interposer selected to exhibit a high thermal impedance sufficient to isolate any heat generated from opto-electronic circuitry from impacting the performance of the laser source.

### CROSS-REFERENCE TO RELATED APPLICATIONS

This application claims the priority of U.S. Provisional Application 63/460,983, filed Apr. 21, 2023 and herein incorporated by reference.

### BACKGROUND OF THE INVENTION

High density optical/electrical (O/E) interconnection arrangements typically employ a set of photonic integrated circuits and related electrical signal routing/switching ASICs disposed on a single substrate (such as a printed circuit board (PCB)). Some arrangements also include one or more laser sources also mounted on the PCB. To date, the optical interconnections between various ones of the elements have used arrays of optical fibers, which necessitates providing optical alignment between the core regions of the fibers and the optical waveguides included in the photonic integrated circuits.

FIG. 1 illustrates an example prior art optical interconnection architecture as described in U.S. Pat. No. 10,725,254 entitled “High Density Opto-Electronic Interconnection Configuration Utilizing Passive Alignment”, which issued on Jul. 28, 2020 and is assigned to the assignee of this application. A set of O/E circuits 1 is shown in FIG. 1 as positioned around a routing/switching ASIC 2, with all of these components mounted on a PCB 3. A set of laser sources 4 (referred to at times hereinafter as “laser engines 4”) is included with the interconnection arrangement, but physically separated from the other elements and coupled to O/E circuits 1 via polarization maintaining (PM) fibers 5. Additional fiber arrays 6 (which may comprise standard, single mode fiber) are used to provide optical signal paths between O/E circuits 1 and a backplane/faceplate coupling element 7 that functions as an interface to exterior components.

This architecture was particularly configured to maintain a large physical separation between laser engines 4 and the active electronics included in O/E circuits 1 and ASIC 2 so that the heat generated by the electronics would not adversely impact the operation of the laser diodes included in laser engines 4 (e.g., cause temperature-induced changes in the operating wavelength, decrease operational lifetime of the laser diodes, etc.). While this physical separation does provide the necessary thermal isolation, it is at the cost of requiring the use of arrays of PM fibers to couple the output beams from laser engines 4 to the optical signal paths in O/E circuits 1. Further, the fiber arrays require active alignment, as well as additional fiber-supporting components to be included in both the laser engines and the optical circuits.

### SUMMARY OF THE INVENTION

The present invention proposes an architecture for a high density opto-electronic interconnection assembly that eliminates the need for a physical separation between the laser engines and associated “thermally active” electronic circuitry and, as a result, eliminates the need to utilize PM fibers to provide optical coupling between the laser engines and optical waveguides included within the O/E circuitry. More particularly, a separation between these elements may now be small enough such that the output signals (i.e., free-space propagating beams) from the laser engine may be directly coupled into sidewall edge terminations of waveguides formed in an adjacent photonic integrated circuit.

In accordance with embodiments of the present invention, laser engine components are disposed on an interposer formed of a material selected to exhibit a thermal impedance that is high enough to provide thermal isolation between the laser engine and any heat-generating opto-electronic circuitry that may be included in the configuration. In one example, glass may be used as the interposer, since most glass materials exhibit a relatively high thermal impedance value (for the purposes of the present invention, “high” thermal impedance means a thermal impedance greater than that exhibited by the silicon material typically used in the formation of an interposer element). The selection of glass as a high thermal impedance interposer material is considered to be only one example; in general, the interposer may be formed of any other material with a thermal impedance greater than silicon.

By virtue of providing sufficient thermal isolation, a more compact high density opto-electronic interconnection assembly may be employed, with the thermally-isolated laser engine now positioned in relatively close proximity to the associated electronics without fear of temperature-related performance degradation and/or failure modes. The close proximity of the laser engine to the opto-electronic components allows for the free-space optical beam outputs from the laser engine to be directly coupled into associated optical waveguides, thereby eliminating the need for optical fiber connections between the laser engine and the remaining components. This thermally isolated, compact configuration provided in accordance with the principles of the present invention is considered to not only simplify manufacturing processes and reduce costs accordingly, but also reduce signal loss (by the elimination of multiple fiber interfaces).

The high thermal impedance interposer may be further configured to include through-vias (in one example formed of copper) directly underneath the laser engine (and confined to this area only) to direct any thermal energy generated by the laser diodes themselves into an included thermally conductive structure. More generally, a thermally conductive structure may be disposed in any suitable position relative to the laser diodes so as to direct thermal energy away from the assembly. The thermally conductive structure may take the form of a passive element comprising a material of known thermally conductive properties, or an active element such as a thermo-electric cooler (TEC). Redistribution wiring layers (RDLs) may be formed on the top and bottom surfaces of the interposer and used to provide electrical connections to the individual elements comprising a laser engine assembly (e.g., semiconductor laser diode, thermistor, and TEC, if used).

An exemplary embodiment of the present invention may take the form of an opto-electronic interconnection assembly comprising a high thermal impedance interposer formed of a material exhibiting a thermal impedance value greater than a thermal impedance value of silicon and a laser source module for generating one or more free space output beams, where the laser source module is disposed on a top surface of the high thermal impedance interposer. The interconnection assembly also includes a photonic integrated circuit (PIC) disposed on the top surface of the high thermal impedance interposer and is positioned in proximity to the laser source module, yet remains thermally isolated therefrom by the high thermal impedance of the interposer. The PIC is formed to include a plurality of waveguides terminating along a sidewall thereof such that the free space output beams from the laser source couple directly into associated waveguides of the PIC without requiring the use of coupling optical fibers.

In an exemplary embodiment of the present invention, a thermally conductive element may be disposed in proximity to the laser source module (perhaps on the underside of the high thermal impedance interposer, with conductive vias connecting the two components) to provide a path for removing heat generated by the operation of the laser diodes within the laser source module.

Other and further aspects and embodiments of the invention will become apparent during the course of the following discussion and by reference to the accompanying drawings.

### BRIEF DESCRIPTION OF THE DRAWINGS

Referring now to the drawings, where like numerals represent like parts in several views:

FIG. 1 is an example of a prior art high density opto-electronic interconnection arrangement;

FIG. 2 is a cut-away side view of an exemplary arrangement for providing thermal isolation between a laser engine and associated circuitry formed in accordance with the teachings of the present invention;

FIG. 3 is a simplified view of the arrangement of FIG. 2, illustrating in particular the components associated with providing optical alignment between the laser engine and an adjacent PIC;

FIG. 4 is a top view of the illustration of FIG. 3;

FIG. 5 is a top view of a resultant system assembly using the thermally-isolated combination of a laser engine and associated PIC, formed in accordance with the principles of the present invention; and

FIG. 6 depicts a system-level high density opto-electronic architecture of the present invention, formed using the system assembly as shown in FIG. 5.

### DETAILED DESCRIPTION

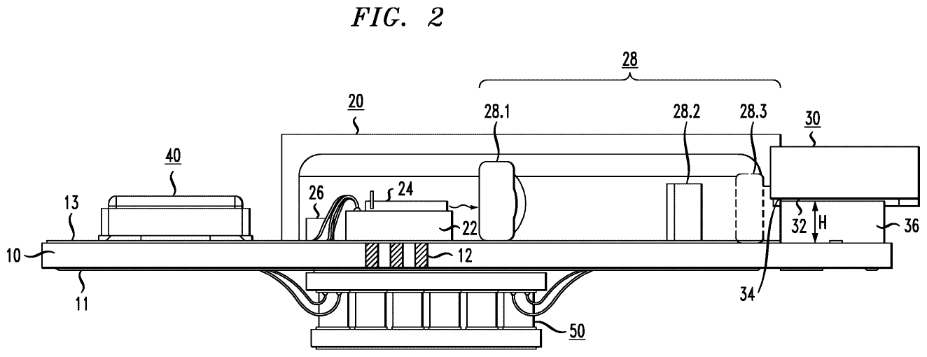

FIG. 2 is a cut-away side view of an exemplary arrangement for providing thermal isolation between a laser engine and associated circuitry in a high density opto-electronic interconnection assembly in accordance with the principles of the present invention. As shown, a high thermal impedance interposer 10 is utilized to support a laser engine 20, as well as a photonic integrated circuit (PIC) 30 disposed in close proximity to laser engine 20. For the purposes of the present invention and as mentioned above, “high” thermal impedance means a thermal impedance greater than that exhibited by the silicon material typically used in the formation of an interposer element).

As will be discussed below, PIC 30 is formed to include optical waveguides that align with the beams created by laser engine 20, providing free space optical interconnection signal paths to the remainder of the interconnection assembly. Also shown in FIG. 2 is an electrical connection interface component 40 that is positioned on high thermal impedance interposer 10 as well. For purposes of discussion, the high thermal impedance interposer may be referred to hereafter as a “glass” interposer with the understanding that other materials may be used as well.

Laser engine 20 is shown in this side view as including a laser submount 22 upon which a plurality of individual (discrete) laser diodes 24 is disposed in a linear array formation (only a single laser diode 24 being visible in this side view). A thermistor 26 is positioned in proximity to laser submount 22 and used for ambient temperature monitoring in a well-known manner. The optical output beams from laser diodes 24 pass through passive coupling optics 28 before exiting laser engine 20. In this example, passive coupling optics 28 includes a lens 28.1, as well as perhaps an optical isolator 28.2, and a focusing lens 28.3. This collection of elements forming passive coupling optics 28 is considered as only one example, other configurations may not require an isolator (for example), or may not require a focusing lens, etc. While the view of FIG. 2 illustrates a housing (lid) for laser engine 20, this is for illustrative purposes only and is not considered as part of the inventive structure.

PIC 30 is shown as positioned adjacent (i.e., in close proximity) to laser engine 20 and is formed to include an array of optical waveguides 32 that terminate along a sidewall 34 of PIC 30. As noted above, the thermal isolation provided by glass interposer 10 allows for laser engine 20 to be positioned close enough to PIC 30 so that optical fibers are not required to couple the output beams from laser engine 20 into the optical waveguides of PIC 30. Instead, the output beams from laser engine 20 may propagate as free space beams (propagating through included passive coupling optics 28) into waveguides 32 formed in PIC 30. In many cases, the output beams take the form of TE polarized beams and would conventionally require the use of polarization-maintaining (PM) fiber to couple the TE polarized beams into waveguides 32.

Again, the side view of FIG. 2 illustrates only a single waveguide 32 that is in optical alignment with illustrated laser diode 24. As will be evident in the following drawings, the array of waveguides 32 is disposed to be in optical alignment with the linear array of laser diodes 24 upon assembly.

In this example, PIC 30 itself is disposed on a base element 36 that is configured to present optical waveguides 32 at a height H which is defined as the optical axis of laser engine 20. As will be discussed below, additional adjustments in the optical alignment between laser diodes 24 and waveguides 32 may use an active alignment technique, where a “golden” PIC is disposed on base element 36 and the position of various elements within passive coupling optics 28 is adjusted with respect to waveguides 32 to achieve maximum optical coupling.

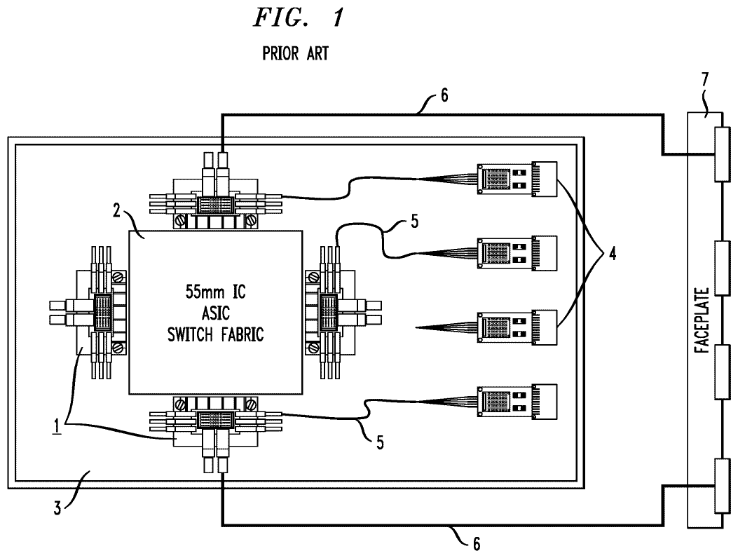

As a result of using a high thermal impedance interposer, which permits adjacent positioning of laser engine 20 and PIC 30, free-space coupling of the generated laser output signals is achieved and thus eliminates the need to utilize PM fibers to provide optical coupling as required in the prior art (see, for example, the prior art configuration of FIG. 1), where typically polarized beams (TE, or possibly TM) are provided as the output from the laser diodes.

While glass interposer 10 provides effective thermal isolation between laser engine 20 and the remaining electrical circuitry included in the high density opto-electronic interconnection assembly, this same thermal isolation property may impede the ability of laser engine 20 itself to dissipate the heat generated by the operation of laser diodes 24. Thus, in further accordance with an exemplary embodiment of the present invention, glass interposer 10 may be formed to include a plurality of vias 12 (referred to hereafter as “through-glass vias” or simply “TGVs”) that function to quickly draw generated heat away from laser engine 20. TGVs 12 terminate on a thermally conductive element 50 that is disposed on the underside 11 of glass interposer 10.

As illustrated in FIG. 2, the plurality of TGVs 12 is confined in location to overlap laser submount 22, with thermally conductive element 50 positioned accordingly. In a preferred embodiment, TGVs 12 are formed of copper, although other materials with a suitable heat transfer characteristic may be used. Bond pads may be formed on both top surface 13 and underside 11 of glass interposer 10 to provide the necessary heat transfer path connections between laser diodes 24 and thermally conductive element 50. The remainder of the volume of interposer 10 is uninterrupted glass, which exhibits the desired high thermal impedance and thus provides the necessary thermal isolation between laser engine 20 and the associated thermally active electronic circuitry. The particular configuration of the FIG. 2 embodiment with thermally conductive element 50 disposed on the underside of glass interposer 10 is considered to be only one possible configuration. For example, other arrangements may position thermally conductive element 50 above laser engine 20. Other configurations may be preferable for specific applications.

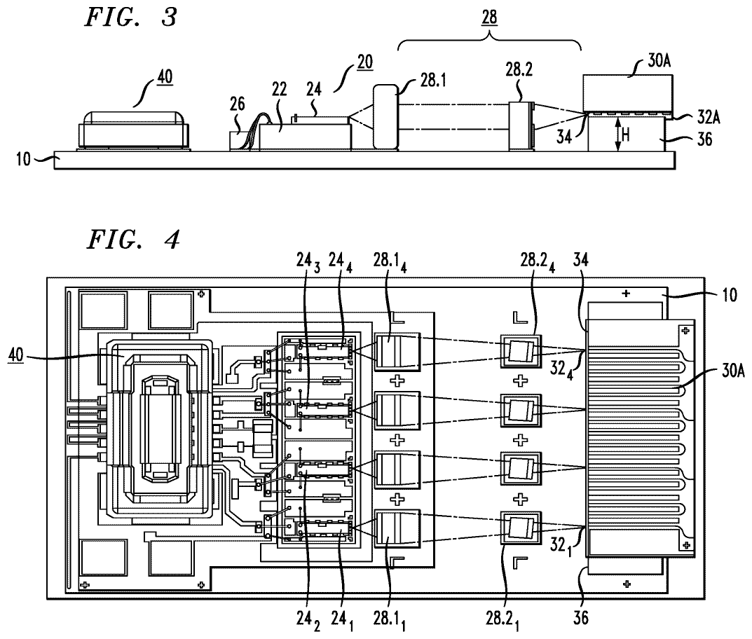

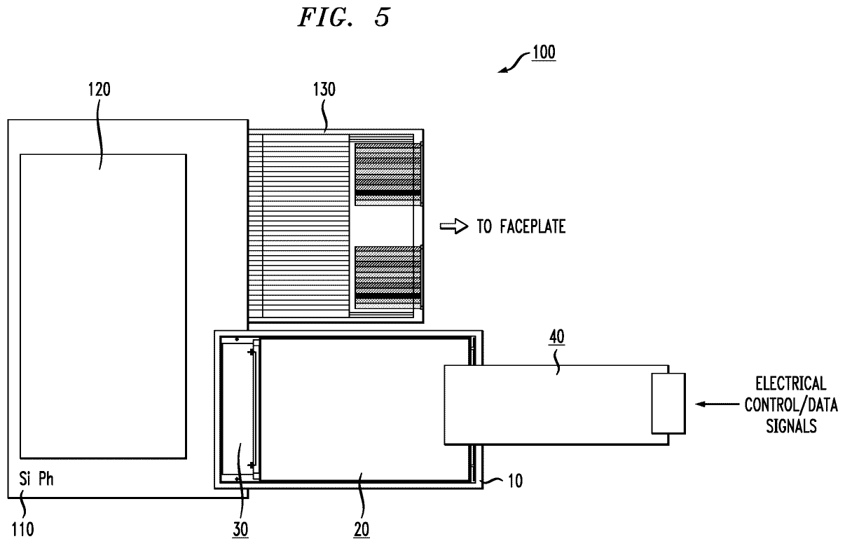

FIG. 3 illustrates a simplified portion of the side view arrangement of FIG. 2 (this view not particularly illustrating optional focusing lens 28.3), in this case illustrating the elements associated with creating optical alignment between the array of output beams generated by laser engine 20 and waveguides 32 of PIC 30. FIG. 4 is a top view of the illustration of FIG. 3, which in this example shows laser engine 20 as including a set of four discrete laser diodes 24 (denoted as 24₁-24₄) and passive optics 28.1, 28.2 associated with each laser diode 24 (the passive optics denoted as 28.1₁-28.1₄ and 28.2₁-28.2₄, respectively). It is to be understood that the illustration of using a set of four individual laser diodes is merely one example; the number of discrete diode devices used is considered to be a design consideration determined by the developers of specific applications.

Alternatively, it is contemplated that the thermal isolation configuration of the present invention may also be used with integrated laser array structures, which may then utilize integrated forms of coupling optics in place of discrete devices. It is to be understood that the proposed thermally isolated configuration of the present invention may be used with any combination of discrete or integrated laser diode configurations in combination with discrete or integrated passive optical coupling devices.

With continuing reference to FIGS. 3 and 4, one procedure for providing optical alignment between laser diodes 24 and waveguides 32 utilizes a pre-formed “standard” PIC 30A (sometimes referred to as a “golden IC” in the art) that is positioned as shown with respect to the optical elements within laser engine 20. Laser diodes 24 are energized, directing their beams (which are typically TE polarized beams) toward “golden” waveguide array 32A of PIC 30A. An active alignment is then performed by adjusting the individual positions of lenses 28.1₁-28.1₄ (and/or focusing lenses 28.3, if included) until a maximum optical coupling is achieved between each laser diode 24ᵢ and its associated waveguide 32ᵢ. Passive optics 28 is then fixed in place using a standard epoxy or similar material. Once properly positioned, standard PIC 30A is removed, and the actual photonic PIC 30 to be used in the finished product is positioned in its place (not shown). Inasmuch as a top surface of base element 36 and a facing surface of PIC 30 may be formed to include alignment fiducials, a passive alignment of these elements maintains the previously-established optical alignment between the array of laser output beams output from laser diodes 24 and waveguide array 32.

Again, it is to be recognized that the thermal isolation provided by glass interposer 10 eliminates the requirement for a relatively large physical separation between laser engine 20 and the associated opto-electronic circuitry, and therefore eliminates the need to use a fiber array connection to support the propagation of the generated optical beams from laser engine 20 to associated opto-electronic circuitry (see, for example, the prior art arrangement of FIG. 1). Indeed, the ability to utilize free space optical coupling between laser engine 20 and PIC 30 in accordance with the principles of the present invention simplifies the construction and expense of the associated components.

FIG. 5 is a top view of a resultant system assembly 100 formed using the inventive compact (and thermally isolated) laser engine arrangement of the present invention. The top view of FIG. 5 illustrates laser engine 20, PIC 30, and electrical connector interface component 40 as disposed on glass interposer 10. Electrical connector interface component 40 receives control and data signals used to operate laser diodes 24, thermistor 26 and (if necessary) thermally conductive element 50.

As discussed above, by virtue of using a high thermal impedance interposer 10, laser engine 20 may be positioned in close proximity (via PIC 30) to an associated active silicon photonic (SiPh) die 110 and an electrical IC 120. In this example, electrical IC 120 is flip-chip mounted on SiPh die 110, with the understanding that other configurations of associated O/E circuitry are possible. In accordance with the principles of the present invention, the heat generated by electrical IC 120 remains isolated from laser engine 20 by the presence of glass interposer 10. Also illustrated in assembly 100 is an optical fiber interconnection component 130, which provides optical signal coupling between SiPh die 110 and external signal paths.

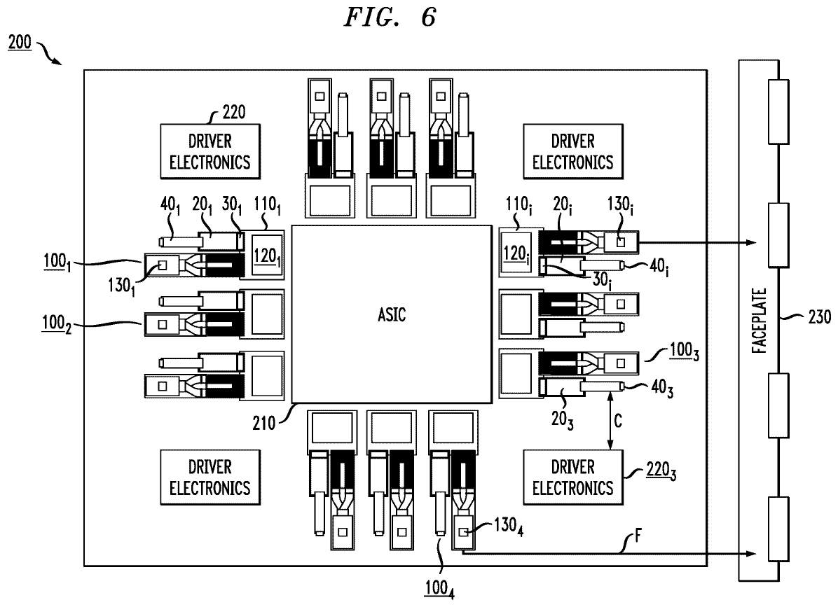

FIG. 6 depicts a system-level high density opto-electronic architecture 200 based upon utilizing the system assembly 100 of FIG. 5. Structured in a manner similar to the prior art arrangement of FIG. 1, a plurality of individual system assemblies 100 is disposed to surround a centrally-located ASIC 210. Example assemblies 100₁, 100₂ and 100₃ are specifically identified in FIG. 6. In accordance with the principles of the present invention, each assembly 100ᵢ may include its own laser engine 20ᵢ in a thermally isolated arrangement with the remaining circuitry. No optical fibers (PM or otherwise) are necessary to form signal paths between the laser diodes within a laser engine 20ᵢ and associated SiPh die 110ᵢ (as compared to the need for PM fibers 5 in the prior art arrangement of FIG. 1). An example electrical connection C is shown in FIG. 6 between electrical connector 40₃ and associated driver electronics 220₃ included in architecture 200. An example fiber array connection F is shown in FIG. 6 between optical fiber interconnection component 130₄ and a faceplate 230 of architecture 200.

In comparison to the prior art configuration of FIG. 1, optical interconnection architecture 200 may result in presenting a smaller footprint arrangement, yet allow for individual laser engines to be associated with each individual system assembly 100 in a thermally isolated arrangement.

While the principles of the invention have been described herein, it is to be understood by those skilled in the art that this description is made only by way of example and not as a limitation as to scope of the invention. Modifications and substitutions by one of ordinary skill in the art are considered to be within the scope of the present invention, which is not to be limited except by the following claims.

What is claimed is:

1. An opto-electronic interconnection assembly, comprising
a high thermal impedance interposer formed of a material exhibiting a thermal impedance value greater than a thermal impedance value of silicon;
a laser source module for generating one or more free space output beams, the laser source module disposed on a top surface of the high thermal impedance interposer;
a photonic integrated circuit disposed on the top surface of the high thermal impedance interposer in proximity to the laser source module so as to form a thermally isolated configuration, the photonic integrated circuit formed to include a plurality of waveguides terminating along a sidewall thereof such that the free space output beams from the laser source couple directly into associated waveguides of the photonic integrated circuit without utilizing coupling optical fibers.

2. The opto-electronic interconnection assembly as defined in claim 1, further comprising:
a thermally conductive element disposed in proximity to the laser source module for transferring heat generated by the laser source module away from the opto-electronic interconnection assembly.

3. The opto-electronic interconnection assembly as defined in claim 2, wherein the thermally conductive element is disposed on an opposite, bottom surface of the high thermal impedance interposer and positioned beneath the laser source module, and the opto-electronic interconnection assembly further comprises:
a plurality of conductive vias formed through the interposer between the laser source module and the thermally conductive element, providing a thermal path for heat generated by the laser source module to be directed away from the photonic integrated circuit.

4. The opto-electronic interconnection assembly as defined in claim 1, wherein the laser source module comprises
a plurality of laser diode elements disposed to emit an array of output beams; and
an array of passive coupling elements disposed in a one-to-one arrangement with the array of output beams, the passive coupling elements selected to focus the generated free space output beams into the plurality of waveguides included in the photonic integrated circuit.

5. The opto-electronic interconnection assembly as defined in claim 4 where the plurality of laser diode elements comprises a plurality of discrete laser diode devices.

6. The opto-electronic interconnection assembly as defined in claim 4 where the plurality of laser diode elements comprises an integrated array of laser diode emitter structures.

7. The opto-electronic interconnection assembly as defined in claim 4 where the array of passive coupling elements comprises a plurality of discrete passive components.

8. The opto-electronic interconnection assembly as defined in claim 4 wherein the array of passive coupling elements comprises an integrated configuration of passive coupling components.

9. The opto-electronic interconnection assembly as defined in claim 3, wherein the plurality of conductive vias comprise a plurality of copper vias.

10. The opto-electronic interconnection assembly as defined in claim 2, wherein the thermally conductive element comprises a passive component having a composition selected for thermal conductivity properties.

11. The opto-electronic interconnection assembly as defined in claim 2, wherein the thermally conductive element comprises a thermo-electric cooler.

12. The opto-electronic interconnection assembly as defined in claim 1, wherein the high thermal impedance interposer comprises a glass material.

13. The opto-electronic interconnection assembly as defined in claim 1, wherein the laser source module generates one or more polarized output beams, thereafter propagating as free spaced polarized beams into the plurality of optical waveguides formed within the photonic integrated circuit.

14. The opto-electronic interconnection assembly as defined in claim 13 wherein the one or more polarized output beams comprises an array of TE polarized output beams, thereafter coupled into an array of optical waveguides formed within the photonic integrated circuit.

15. A high density opto-electronic integrated assembly, comprising:
an application-specific electronic integrated circuit configured to provide routing and switching of various electrical communication signals; and
a plurality of opto-electronic assemblies coupled to the application-specific electronic integrated assembly, each opto-electronic assembly comprising:
an opto-electronic integrated circuit providing direction connection to the application-specific electronic integrated circuit;
an optical fiber interface connection to external optical signal paths; and
an opto-electronic interconnection assembly, comprising
a high thermal impedance interposer formed of a material exhibiting a thermal impedance value greater than a thermal impedance value of silicon;
a laser source module for generating one or more free space output beams, the laser source module disposed on a top surface of the high thermal impedance interposer; and
a photonic integrated circuit disposed on the top surface of the high thermal impedance interposer in proximity to the laser source module so as to form a thermally isolated configuration, the photonic integrated circuit formed to include a plurality of waveguides terminating along a sidewall thereof such that the free space output beams from the laser source couple directly into associated waveguides of the photonic integrated circuit without utilizing coupling optical fibers.
